(19) United States
(12) Patent Application Publication
(10) Pub. No.: US 2011/0028002 A1
(43) Pub. Date: Feb. 3, 2011

(54) SEMICONDUCTOR DEVICE AND METHOD OF MANUFACTURING THE SAME

(75) Inventor: Toshiyuki HIROTA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/844,390

(22) Filed: Jul. 27, 2010

(30) Foreign Application Priority Data
Jul. 29, 2009 (JP) 2009-176781

(51) Int. Cl. H01L 21/314

(52) U.S. Cl. 438/761; 257/E21.266

(57) ABSTRACT

A method of forming a semiconductor device includes the following processes. A metal nitride film is formed with a thickness of 3 nm or less over a substrate. The metal nitride film is oxidized to form a metal oxide film. A set of the formation of the metal nitride film and the oxidation of the metal nitride film is repeated, to form a stack of the metal oxide films over the substrate.

### BACKGROUND OF THE INVENTION

1. Field of the Invention

The present invention relates to a semiconductor device and a method of manufacturing a semiconductor device.

Priority is claimed on Japanese Patent Application No. 2009-176781, filed Jul. 29, 2009, the content of which is incorporated herein by reference.

2. Description of the Related Art

In recent years, the requirement for a high-performance capacitor with reduced dimensions has been increasing. For these purposes, a thin metal oxide film of the capacitor has been on the development. In a DRAM, the capacitor needs to have a high capacitance.

An insulating film (dielectric film) with a high dielectric constant is used in the capacitor. Typical examples of the insulating film (metal oxide film) for the capacitor with a high dielectric constant may include, but is not limited to, metal oxides, such as titanium oxide (TiO₂) and zirconium oxide (ZrO₂). Among the metal oxides, titanium oxide (TiO₂) can be used for an insulating film for the capacitor with a high relative permittivity of from about 40 to about 80.

It is preferable that the insulating film (metal oxide film) for a capacitor in the DRAM is formed by an ALD (Atomic Layer Deposition) method or by a CVD (Chemical Vapor Deposition) method. These methods can be applied to form electrodes with various shapes. A uniform metal oxide film can be formed on a three-dimensional shape electrode such as a cylindrically shaped electrode by using the ALD method or the CVD method.

Japanese Unexamined Patent Application, First Publications, Nos. JP-A-2007-318147, JP-A-08-64780, and JP-A-2000-150817 disclose the following techniques. As a method of forming the insulating film (metal oxide film) for a capacitor using the ALD method, the following method is known. A source gas including a metal material is supplied onto an electrode and the metal material is adsorbed onto the electrode to form a thin film of the metal material. The thin film is then oxidized by an ozone (O₃) gas or an oxygen (O₂) gas. As another method of forming the insulating film (metal oxide film) for a capacitor, the following method is known. A thin film made of metal nitride such as titanium nitride is formed. The thin film is completely oxidized to form a metal oxide film such as a titanium oxide film.

### SUMMARY

In one embodiment, a method of forming a semiconductor device may include, but is not limited to, the following processes. A metal nitride film is formed with a thickness of 3 nm or less over a substrate. The metal nitride film is oxidized to form a metal oxide film. A set of the formation of the metal nitride film and the oxidation of the metal nitride film is repeated, to form a stack of the metal oxide films over the substrate.

In another embodiment, a method of forming a semiconductor device may include, but is not limited to, the following processes. A metal nitride film with a predetermined thickness is formed over a substrate. The metal nitride film is oxidized to form a metal oxide film. A set of the formation of the metal nitride film and the oxidation of the metal nitride film is repeated, to form a stack of the metal oxide films over the substrate. The predetermined thickness is set to prevent an occurrence of a blister under the metal oxide film due to the oxidizing of the metal nitride film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a flowchart illustrating a method for forming a titanium oxide film by using an ALD method;

FIG. 2 is a flowchart illustrating a process of finally forming a titanium oxide film using a CVD method;

FIG. 3 is a plan view illustrating a layout of memory cells of a DRAM, wherein the memory cell includes a capacitor that includes a capacitor insulating film;

FIG. 4 is a cross-sectional view illustrating a sectional structure of the semiconductor device taken along the line A-A′ of FIG. 3;

FIG. 5 is a cross-sectional view illustrating a semiconductor device in a step involved in a method of forming the semiconductor device of FIG. 4;

FIG. 6 is a cross-sectional view illustrating a semiconductor device in a step, subsequent to the step of FIG. 5, involved in a method of forming the semiconductor device of FIG. 4; and

FIG. 7 is a cross-sectional view illustrating a semiconductor device in a step, subsequent to the step of FIG. 5, involved in a method of forming the semiconductor device of FIG. 4.

### DETAILED DESCRIPTION OF THE PREFERRED EMBODIMENTS

Before describing the present invention, the related art will be explained in detail, in order to facilitate the understanding of the present invention.

The method that directly oxidizes the metal thin film, which is adsorbed to the electrode, to form the metal oxide film using the ALD method, has the following phenomena will occur. When the metal oxide film formed by the ALD method is used as an insulating film or a capacitor insulating film for a capacitor, it is difficult to obtain desired characteristics or performances of the capacitor. This is caused because impurities such as chlorine or fluorine contained in the source gas including the metal material will remain in the metal oxide film. The deposition rate of the metal oxide film by the ALD method is low, which will result in reduction in the productivity of the metal oxide film.

A metal nitride film is deposited so that the metal nitride film has a thickness which is finally required, before the metal nitride film is then oxidized to form a metal oxide film. In the method of oxidizing the metal nitride film which has been deposited on the electrode in order to form the metal oxide film, a blister will occur between the electrode and the insulating film or the metal oxide film for a capacitor. The blister is caused by the damage of the metal oxide film. When a capacitor with the damage of the metal oxide film is formed in this state, a large leakage of current is generated. It is difficult to obtain a capacitor with desired characteristics or performances.

The blister between the electrode and the insulating film or the metal oxide film for a capacitor is caused by a phenomenon that a nitrogen (N₂) gas is confined between the metal nitride film and the electrode. The nitrogen (N₂) gas is generated when the metal nitride film is oxidized. The collected nitrogen (N₂) gas is confined between the electrode and the insulating film or the metal oxide film for a capacitor. The nitrogen (N₂) gas confinement will cause the blister between the electrode and the insulating film or the metal oxide film for a capacitor. Therefore, the method according to the related art that oxidizes the metal nitride film to form the metal oxide film will make it difficult to maintain good current leakage characteristics of the capacitor. It is difficult to form a semiconductor element such as a capacitor or a DRAM including a capacitor with a high reliability.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device may include, but is not limited to, the following processes. A metal nitride film is formed with a thickness of 3 nm or less over a substrate. The metal nitride film is oxidized to form a metal oxide film. A set of the formation of the metal nitride film and the oxidation of the metal nitride film is repeated, to form a stack of the metal oxide films over the substrate.

In some cases, the metal nitride film is formed by an atomic layer deposition process.

In some cases, the atomic layer deposition process may include, but is not limited to, the following processes. A metal film including a metal material of the metal nitride film is formed. A nitridation of the metal film is carried out by supplying a nitriding gas onto the metal film. The formation of the metal film and the nitridation of the metal film are repeated, to form a stack of the metal nitride films over the substrate.

In some cases, the method may further include, but is not limited to, forming an electrode over the substrate before forming the metal film, wherein forming the metal film is performed by absorbing the metal material on a surface of the electrode.

In some cases, the metal nitride film may include a nitride of at least one metal which is selected from the groups consisting of titanium, aluminum, hafnium, zirconium, tantalum, and lanthanum.

In some cases, forming the metal film may be performed by supplying a source gas to the substrate. The source gas includes at least one of TiCl₄, Ti(OCHMe₂)₄, tetramethoxy titanium, and Ti[N(CH₃)₂]₄.

In some cases, the nitriding gas may be an NH3 gas.

In some cases, the NH₃ gas may be activated by a remote plasma process.

In some cases, the metal nitride film may be oxidized in an atmosphere which contains at least one of oxygen, ozone, a mixture gas of oxygen and ozone, and nitrogen monoxide.

In some cases, the metal nitride film may be formed by a chemical vapor deposition process.

In some cases, a source gas including TiCl₄ and NH₃ may be supplied to the substrate to form the metal nitride film.

In some cases, the metal nitride film may be formed with a thickness of 1 nm or less.

In some cases, the metal nitride film may be formed with a thickness of 0.5 nm or less.

In some cases, the metal oxide film may be a titanium oxide film having mainly a rutile crystal phase.

In some cases, the metal nitride film may be formed in a temperature range from 400° C. to 600° C.

In another embodiment, a method of forming a semiconductor device may include, but is not limited to, the following processes. A metal nitride film with a predetermined thickness is formed over a substrate. The metal nitride film is oxidized to form a metal oxide film. A set of the formation of the metal nitride film and the oxidation of the metal nitride film is repeated, to form a stack of the metal oxide films over the substrate. The predetermined thickness is set to prevent an occurrence of a blister under the metal oxide film due to the oxidizing of the metal nitride film.

In some cases, the metal oxide film may be a titanium oxide film.

In some cases, the titanium oxide film may include a rutile crystal phase mainly.

In some cases, the predetermined thickness may be set to 3 nm or less.

In some cases, the predetermined thickness may be set to 0.5 nm or less.

### Embodiments

Hereinafter, a method of manufacturing a semiconductor device according to a first embodiment of the invention will be described with reference to the accompanying drawings.

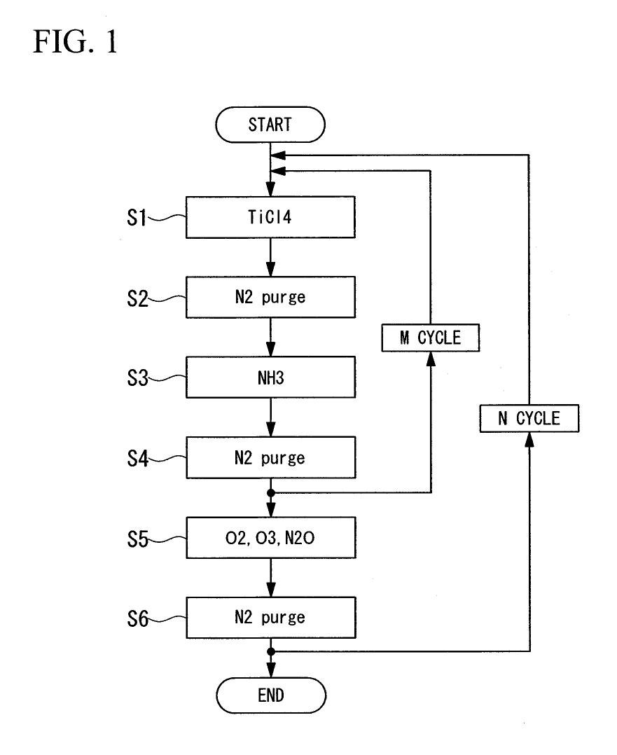

FIG. 1 is a flowchart illustrating a method for forming a titanium oxide film by using an ALD method.

The method of manufacturing the semiconductor device according to this embodiment may include, but is not limited to, the following processes. A source gas is supplied onto a substrate to form a metal nitride film with a thickness of 3 nm or less using the ALD method. The metal nitride film is oxidized to form a metal oxide film. A series of these processes will be repeated plural times, thereby forming stacked metal oxide films over the substrate.

In this embodiment, a titanium nitride film is formed as the metal nitride film, and a titanium oxide film is formed as the metal oxide film. The method includes the following processes.

A deposition apparatus (not shown) is prepared. The deposition apparatus includes a reaction chamber, and a gas supply system. The reaction chamber is used for depositing a metal film by using the ALD method. The gas supply system is configured to introduce oxygen (O₂), ozone (O₃), a mixed gas of oxygen and ozone, or a nitrous oxide (N₂O) as an oxidizing agent.

The formation temperature in the reaction chamber of the deposition apparatus can be set depending on the state of the titanium oxide film. When a titanium oxide film having mainly a rutile phase is formed, the formation temperature can be set in the range of 400° C. to 600° C. When a titanium oxide film mainly having an anatase phase is formed, the formation temperature can be set in the range of 350° C. to 400° C. When an amorphous titanium oxide film is formed, the formation temperature can be set to less than 350° C.

A semiconductor substrate with a bottom electrode 113 for a capacitor is prepared. The bottom electrode 113 may be made of, but not limited to, ruthenium (Ru), platinum (Pt), iridium (Ir), titanium nitride (TiN), or tungsten (W). The semiconductor substrate is put into the reaction chamber of the deposition apparatus.

A source gas is supplied onto the bottom electrode 113 in the reaction chamber to deposit a titanium nitride film with a thickness of 3 nm or less over the bottom electrode 113. This deposition process will be described below with reference to FIG. 1.

In Step S1, TiCl₄, which may include an inert gas as a carrier gas, is supplied as the source gas into the reaction chamber in which the semiconductor substrate is placed. TiCl₄ is adsorbed to the surface of the bottom electrode 113. The supply of the TiCl₄ gas is then terminated. Evacuation is performed without supplying any gas into the reaction chamber.

The source gas is not limited to TiCl₄, but an organic-based precursor such as TTIP (Ti(OCHMe₂)₄:titanium tetraisopropoxide), tetramethoxy titanium (Ti(OCH₃)₄), or TDMAT (Ti[N(CH₃)₂]₄:tetrakis(dimethylamino)titanium), may be used as the source gas.

In Step S2, an N₂ gas for purge is supplied into the reaction chamber. The supply of the N₂ gas is terminated. Evacuation is performed without supplying any gas into the reaction chamber.

In Step S3, an NH₃ gas is supplied to the reaction chamber. When NH₃ is insufficiently decomposed, NH₃ may be activated by a remote plasma method and then introduced into the reaction chamber. Then, the supply of the NH₃ gas stops and evacuation is performed without supplying any gas into the reaction chamber.

In Step S4, the N₂ gas for purge is supplied into the reaction chamber again. Then, the supply of the N₂ gas stops and evacuation is performed without supplying any gas into the reaction chamber.

In this case, NH₃ reacts with TiCl₄ which has been adsorbed to the surface of the bottom electrode 113 by Steps S1 to S4. A titanium nitride (TiN) film with a thickness corresponding to one cycle of the ALD method is formed on the surface of the bottom electrode 113. It is possible to adjust the thickness of the titanium nitride film by repeating Steps S1 to S4 in M cycles, where M is the integer number that is equal to or greater than 1. In this case, the thickness of the metal nitride film such as a titanium nitride film in this embodiment deposited by M cycles of Steps S1 to S4 is equal to or less than 3 nm. When the thickness of the titanium nitride film is equal to or less than 3 nm, it is possible to prevent the occurrence of the blister in the titanium nitride film due to an oxidizing process of Step S5.

In order to improve the effect of preventing the occurrence of the blister in the titanium nitride film, it is preferable to minimize the thickness of the titanium nitride film. The thickness of the titanium nitride film deposited in Steps S1 to S4 is preferably equal to or less than 1 nm and more preferably equal to or less than 0.5 nm.

When the titanium oxide film having mainly a rutile phase is formed, it is preferable to minimize the thickness of the titanium nitride film. The thickness of the titanium nitride film deposited in Steps S1 to S4 is preferably equal to or less than 1 nm and more preferably equal to or less than 0.5 nm, in addition to setting the deposition temperature, for example, in the range of 400° C. to 600° C., of the titanium nitride film in Steps S1 to S4.

When the titanium oxide film mainly having an anatase phase is intentionally formed, it is preferable to maximize the thickness of the titanium nitride film. If the titanium nitride film is too thick, a blister may occur when oxidation is performed in Step S5. Therefore, the thickness of the titanium nitride film is thick as possible in the range of 3 nm or less.

The kind of metal material included in the titanium nitride film formed in Step S4 is not limited to one, but the titanium nitride film may include plural kinds of metal materials. The titanium nitride film may be doped with a metal material, such as aluminum (Al), zirconium (Zr), hafnium (Hf), zirconium (Zr), tantalum (Ta), or lanthanum (La), in addition to titanium (Ti). In this case, finally, a titanium oxide film including a metal material in addition to titanium is formed. The kind of metal material included in the titanium nitride film may be adjusted depending on, for example, the desired electrical characteristics such as a leakage of current.

In Step S5, the titanium nitride film is oxidized and a titanium oxide film is formed. The oxidizing agent gas may be O₂, O₃, or N₂O. In addition, for example, N₂, He, or Ar may be included as a diluted gas. Then, the supply of the oxidizing agent gas stops and evacuation is performed without supplying any gas into the reaction chamber.

In Step S6, the N₂ gas for purge is supplied into the reaction chamber again. Then, the supply of the N₂ gas stops and evacuation is performed without supplying any gas into the reaction chamber.

In this case, Steps S1 to S6 form one cycle and are repeated in N cycles, where N is an integer that is equal to or greater than 1. When Steps S1 to S6 are repeated in N cycles, the number of cycles in Step S5 in which oxidation is performed increases and the time required to finally form the titanium oxide film with a necessary thickness increases. Therefore, in one cycle of Steps S1 to S6, Steps S1 to S4 may be repeated in M cycles such that the titanium nitride film with the optimal thickness in the range of 3 nm or less is deposited according to productivity. In this way, a titanium oxide film having a stacked structure is formed with a desired thickness on the metal of the bottom electrode 113 for a capacitor.

In this embodiment, the thickness of the titanium nitride film oxidized by one oxidizing process is equal to or less than 3 nm and the deposition and oxidation of the titanium nitride film are repeatedly performed. In this way, it is possible to form a titanium oxide film with a desired thickness while preventing the occurrence of a blister in the titanium oxide film. In particular, the thickness of the titanium nitride film is equal to or less than 1 nm or 0.5 nm. In this case, it is possible to form a titanium oxide film having mainly a rutile phase, while preventing the occurrence of a blister in the titanium oxide film. In this way, it is possible to form a semiconductor element and a semiconductor device with high reliability.

In this embodiment, the titanium oxide film is formed. The embodiment may be used to form a metal oxide film including other metal materials.

Specifically, the first embodiment may be used to form a metal oxide film including one kind of metal material selected from a group of titanium (Ti), aluminum (Al), hafnium (Hf), zirconium (Zr), tantalum (Ta), and lanthanum (La). In addition, the first embodiment may be applied to form a metal oxide film including two or more kinds of metal materials selected from them. The metal oxide film including the metal materials may be used as an insulating film.

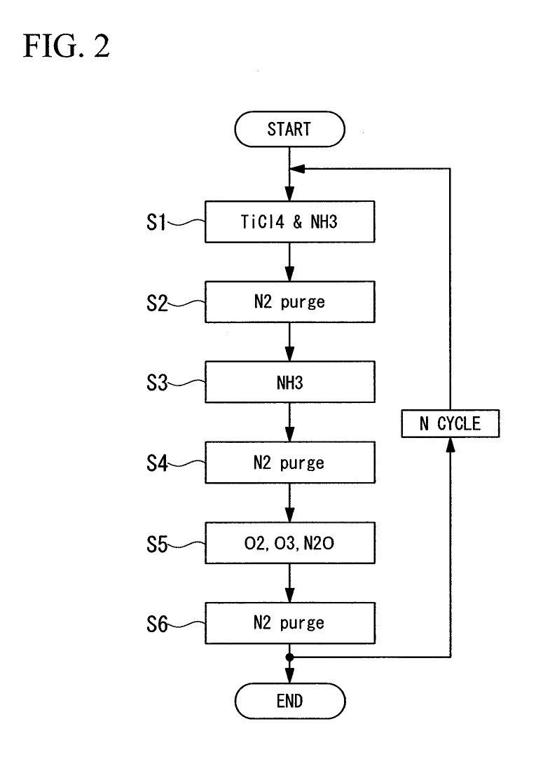

A method of manufacturing a semiconductor device according to a second embodiment of the invention will be described with reference to FIG. 2.

FIG. 2 is a flowchart illustrating a process of finally forming a titanium oxide film using a CVD method.

The embodiment of manufacturing the semiconductor device according to this embodiment includes repeatedly performing a process of supplying a source gas onto a substrate, depositing a metal nitride film with a thickness of 3 nm or less using the CVD method, and oxidizing the metal nitride film to form a metal oxide film plural times, thereby forming a stacked film including the metal oxide films on the substrate.

In this embodiment, a titanium nitride film is formed as the metal nitride film, and a titanium oxide film is formed as the metal oxide film. The processes will be described.

Before the process will be performed, a deposition apparatus (not shown) is prepared. The deposition apparatus includes a reaction chamber that can deposit a metal film using the CVD method and a gas supply system that can introduce oxygen (O₂), ozone (O₃), a mixed gas of oxygen and ozone, or a nitrous oxide (N₂O) as an oxidizing agent. The formation temperature in the reaction chamber is set in the range of 400° C. to 600° C. When the formation temperature in the reaction chamber is equal to or less than 400° C., the deposition rate of the titanium nitride film is reduced to a value that is similar to that in the ALD method.

A semiconductor substrate with a bottom electrode 113 for a capacitor is prepared. The bottom electrode 113 may be made of a refractory metal material, such as ruthenium (Ru), platinum (Pt), iridium (Ir), titanium nitride (TiN), or tungsten (W). The semiconductor substrate is put into the reaction chamber of the deposition apparatus.

In the step, a source gas is supplied onto the electrode in the reaction chamber to deposit a titanium nitride film with a thickness of 3 nm or less. This deposition process will be described below with reference to FIG. 2.

In Step S1, a source gas including TiCl₄ and NH₃ is supplied into the reaction chamber in which the semiconductor substrate is placed. The source gas may include an inert gas as a carrier gas. In this way, TiCl₄ and NH₃ are adsorbed to the surface of the electrode. In this case, NH₃ reacts with TiCl₄ adsorbed to the surface of the electrode and a titanium nitride (TiN) film with a thickness corresponding to one cycle of the CVD method is formed on the surface of the electrode.

In this case, the thickness of the metal nitride film is equal to or less than 3 nm. When the thickness of the titanium nitride film is equal to or less than 3 nm, it is possible to prevent the occurrence of a blister in the titanium nitride film due to an oxidizing process of Step S5. In order to improve the effect of preventing the occurrence of the blister in the titanium nitride film, it is preferable to minimize the thickness of the titanium nitride film. The thickness of the titanium nitride film deposited in Step S1 is preferably equal to or less than 1 nm and more preferably equal to or less than 0.5 nm.

When the titanium oxide film mainly having a rutile phase is formed, it is preferable to minimize the thickness of the titanium nitride film. The thickness of the titanium nitride film deposited in Step S1 is preferably equal to or less than 1 nm and more preferably equal to or less than 0.5 nm.

Then, the supply of the source gas stops. Evacuation is performed without supplying any gas into the reaction chamber.

The kind of metal material included in the titanium nitride film formed in Step S1 is not limited to one, but the titanium nitride film may include plural kinds of metal materials. Specifically, when the titanium nitride film is formed, it may be doped with a metal material, such as aluminum (Al), zirconium (Zr), hafnium (Hf), zirconium (Zr), tantalum (Ta), or lanthanum (La), in addition to titanium (Ti). In this case, finally, a titanium oxide film including a metal material in addition to titanium is formed. The kind of metal material included in the titanium nitride film may be adjusted depending on, for example, the desired electrical characteristics such as a leakage of current.

In Step S2, a N₂ gas for purge is supplied into the reaction chamber. Then, the supply of the N₂ gas stops. Evacuation is performed without supplying any gas into the reaction chamber.

In Step S3, a NH₃ gas is supplied to the reaction chamber. In this way, chlorine (Cl) remaining in the titanium nitride film formed in Step S1 is reduced. Step S3 may be performed according to deposition conditions in Step S1, or it may not necessarily be performed. Then, the supply of the NH₃ gas stops. Evacuation is performed without supplying any gas into the reaction chamber.

In Step S4, the N₂ gas for purge is supplied into the reaction chamber again. Then, the supply of the N₂ gas stops. Evacuation is performed without supplying any gas into the reaction chamber. When Step S3 is not performed, Step S4 is also not performed.

In Step S5, an oxidizing agent gas is supplied into the reaction chamber. In this way, the titanium nitride film is oxidized and a titanium oxide film is formed. The oxidizing agent gas may be O₂, O₃, or N₂O. In addition, for example, N₂, He, or Ar may be included in a diluted gas. Then, the supply of the oxidizing agent gas stops and evacuation is performed without supplying any gas into the reaction chamber.

In Step S6, the N₂ gas for purge is supplied into the reaction chamber again. Then, the supply of the N₂ gas stops and evacuation is performed without supplying any gas into the reaction chamber.

In this case, Steps S1 to S6 form one cycle and are repeated in N cycles (N is an integer that is equal to or greater than 1). In this way, a titanium oxide film with a stacked structure is formed with a desired thickness on the metal of the bottom electrode 113 for a capacitor.

In this embodiment, it is possible to form a good film with a coverage shape using the CVD method using TiCl₄ and NH₃. In addition, when the CVD method is performed under predetermined conditions, it is possible to increase the deposition rate of the titanium nitride film, as compared to the ALD method. Therefore, it is possible to reduce the time required to form the titanium oxide film.

In addition, the thickness of the titanium nitride film oxidized by one oxidizing process is equal to or less than 3 nm and the deposition and oxidation of the titanium nitride film are repeatedly performed. In this way, it is possible to form a titanium oxide film with a desired thickness while preventing the occurrence of a blister in the titanium oxide film. In particular, the thickness of the titanium nitride film is equal to or less than 1 nm or 0.5 nm. In this case, it is possible to form a titanium oxide film mainly having a rutile phase while preventing the occurrence of a blister in the titanium oxide film. In this way, it is possible to form a semiconductor element and a semiconductor device with high reliability.

In this embodiment, the titanium oxide film is formed. However, the embodiment may be used to form a metal oxide film including other metal materials.

Specifically, the embodiment may be used to form a metal oxide film including one kind of metal material selected from a group of titanium (Ti), aluminum (Al), hafnium (Hf), zirconium (Zr), tantalum (Ta), and lanthanum (La). In addition, the invention may be applied to form a metal oxide film including two or more kinds of metal materials selected from them. The metal oxide film including the metal materials may be used as an insulating film.

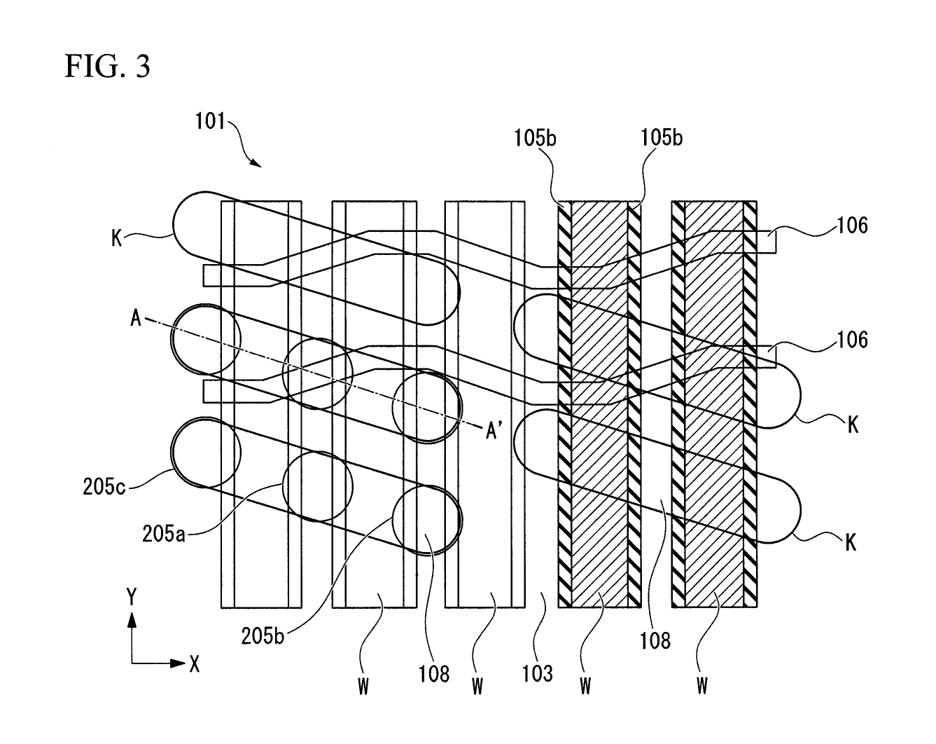

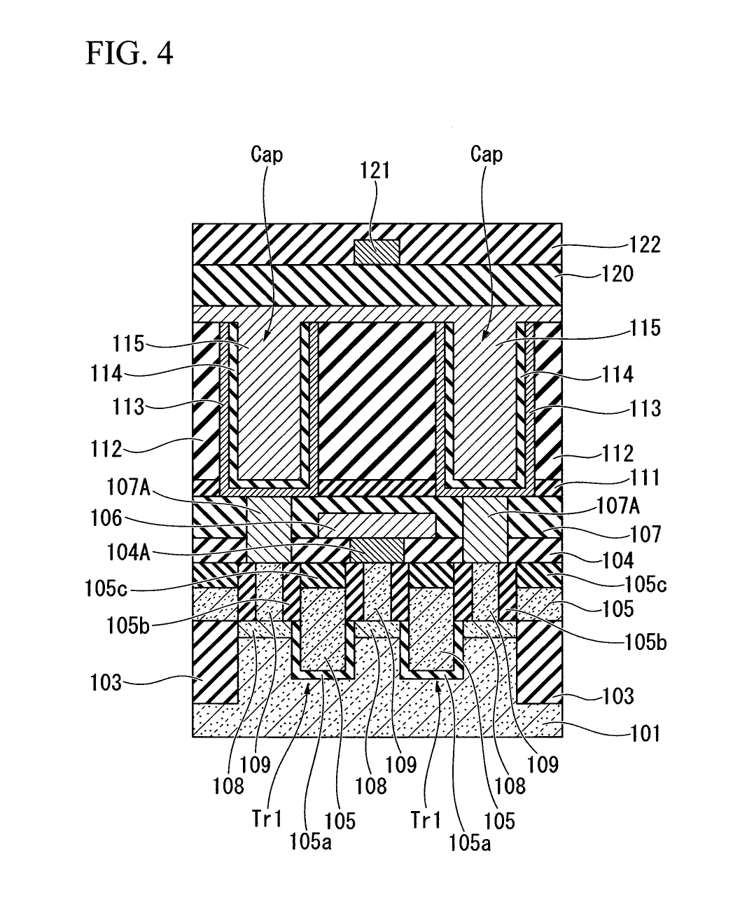

A third embodiment of the invention will be described with reference to FIGS. 3 and 4. In this embodiment, a semiconductor device in which a stacked film including the metal oxide films formed in the above-described embodiment of the invention is used as a capacitor insulating film 114 of a capacitor Cap will be described.

FIG. 3 is a conceptual diagram illustrating the planar layout of a memory cell unit of a DRAM to which the capacitor insulating film 114 is applied. The right side of FIG. 3 is a perspective cross-sectional view illustrating the section of a gate electrode 105, which will be a word line W, and a side wall 105b.

FIG. 4 is a cross-sectional view illustrating the sectional structure of the semiconductor device taken along the line A-A′ of FIG. 3. The capacitor is not shown in FIG. 3, but is shown only in FIG. 4.

First, the memory cell unit will be described with reference to FIG. 3. As shown in FIG. 3, the memory cell unit includes bit lines 106 that extend in the X direction, the word lines W that extend in the Y direction, strip-shaped active regions K, and an impurity diffusion layer 108.

A plurality of bit lines 106 extends in the X direction in a curved line shape (curved shape) and is arranged at a predetermined interval in the Y direction. The word lines W extend in a straight line in the Y direction and are arranged at a predetermined interval in the X direction. Gate electrodes 105 (not shown) are formed at intersections of the word lines W and the active regions K. In addition, the side walls 105b are formed on both sides of the word line W in a line direction (Y direction).

The active regions K are formed in a strip shape on one surface of a semiconductor substrate 101 and are arranged at a predetermined interval so as to be inclined from the upper left to the lower right. In addition, the active regions K are arranged along a layout which is generally called a 6F2 memory cell. The impurity diffusion layers 108 are formed at the center of the active region K and on both sides thereof and function as the source and drain regions of a MOS transistor Tr1, which will be described. In addition, circular substrate contact portions 205a, 205b, and 205c are provided immediately above the source and drain regions (impurity diffusion layer).

Each of the substrate contact portions 205a, 205b, and 205c is arranged such that the center thereof is disposed between the word lines W. The central substrate contact portion 205a is arranged so as to overlap the bit line 106.

The substrate contact portions 205a, 205b, and 205c are disposed at positions where substrate contact plugs 109, which will be described below, are arranged and are also disposed so as to come into contact with the semiconductor substrate 101.

Then, the memory cell unit will be described with reference to FIG. 4. The memory cell unit of the DRAM, which is an example of the semiconductor device according to this embodiment, includes the MOS transistor Tr1, the substrate contact plug 109 and a capacitor contact plug 107A that are connected to the MOS transistor Tr1, and the capacitor Cap that is connected to the MOS transistor Tr1 with the substrate contact plug 109 and the capacitor contact plug 107A interposed therebetween and has a stacked film including the metal oxide film with a thickness of 3 nm or less as the capacitor insulating film 114.

The MOS transistor Tr1 includes the semiconductor substrate 101, an element isolation region 103 that partitions one surface of the semiconductor substrate 101, the active region K partitioned by the element isolation region 103, and two trench gate electrodes 105 that are formed in the active region K.

The semiconductor substrate 101 is made of a semiconductor including P-type impurities at predetermined density, for example, silicon (Si). The element isolation region 103 is formed in the semiconductor substrate 101. The element isolation region 103 is formed by filling a groove formed in the surface of the semiconductor substrate 1 with an insulating film such as a silicon oxide film (SiO₂). In this way, adjacent active regions K are insulated and separated from each other. In the active region K, the impurity diffusion layer 108 in which an N-type impurity, such as phosphorus (P), is diffused is formed on one surface of the semiconductor substrate 101 that is partitioned into three portions by the two trench gate electrodes 105.

The gate electrode 105 is a trench gate electrode, is filled in a groove which is formed in one surface of the semiconductor substrate 101, and protrudes from the groove to the upper side of the semiconductor substrate 101 through the impurity diffusion layer 108.

The gate electrode 105 is a multi-layer film including a polycrystalline silicon film including impurities and a metal film. The polycrystalline silicon film may be formed by doping a film with an N-type impurity, such as phosphorus (P), when the film is formed by the CVD (Chemical Vapor Deposition) method. The metal film may be made of a refractory metal material, such as tungsten (W), tungsten nitride (WN), or tungsten silicide (WSi).

According to the above-mentioned structure, the two gate electrodes 105 function as the gate electrodes of two MOS transistors Tr1 and the impurity diffusion layers 108 functions as the source and drain regions.

A gate insulating film 105a is formed between the gate electrode 105 and the semiconductor substrate 101. The side wall 105b, which is an insulating film made of, for example, a silicon nitride (Si₃N₄), is formed on the side wall of a portion of the gate electrode 105 that protrudes from the semiconductor substrate 101. An insulating film 105c made of, for example, a silicon nitride is formed on the gate electrode 105 and protects the upper surface of the gate electrode 105.

The substrate contact plug 109 is formed so as to contact the impurity diffusion layer 108. The substrate contact plugs 109 are arranged at the positions of the substrate contact portions 205c, 205a, and 205b shown in FIG. 3 and are made of, for example, polycrystalline silicon including phosphorus (P). The width of the substrate contact plug 109 in the lateral (X) direction is defined by the side wall 105b that is provided in an adjacent gate line W, and the substrate contact plug 109 has a self-alignment structure.

An interlayer insulating film 104 is formed so as to cover the insulating film 105c on the gate electrode 105. A bit line contact plug 104A is arranged at the position of the substrate contact portion 205a shown in FIG. 3 such that it passes through the interlayer insulating film 104 and is electrically connected to the substrate contact plug 109. For example, the bit line contact plug 104A is formed by laminating a tungsten (W) film on a barrier film (TiN/Ti), which is a stacked film of titanium (Ti) and titanium nitride (TiN).

A bit line 106 is formed so as to be connected to the bit line contact plug 104A. The bit line 106 is a stacked film of tungsten nitride (WN) and tungsten (W).

A second interlayer insulating film 107 is formed so as to cover the bit lines 106 and the interlayer insulating film 104. The capacitor contact plug 107A is formed such that it passes through the second interlayer insulating film 107 and the interlayer insulating film 104 and is connected to the substrate contact plug 109. The capacitor contact plugs 107A are arranged at the positions of the substrate contact portions 205b and 205c shown in FIG. 3.

A third interlayer insulating film 111 made of a silicon nitride is formed so as to cover the second interlayer insulating film 107, and a fourth interlayer insulating film 112, which is a silicon oxide film, is formed so as to cover the third interlayer insulating film 111.

The capacitor Cap is arranged inside the third interlayer insulating film 111 and the fourth interlayer insulating film 112. The capacitor Cap is formed such that it passes through the third interlayer insulating film 111 and the fourth interlayer insulating film 112 and the bottom electrode 113 is connected to the capacitor contact plug 107A. The capacitor Cap includes the capacitor insulating film 114 that is formed so as to cover the bottom electrode 113 and the side surface of the bottom electrode 113 and an upper electrode 115 that is formed so as to cover the capacitor insulating film 114. The capacitor insulating film 114 is a stacked film of the metal oxide films formed by the method according to the first or second embodiment. The bottom electrode 113 is connected to the MOS transistor Tr1 through the capacitor contact plug 107A.

A fifth interlayer insulating film 120 is formed on the upper electrode 115 and a wiring line 121 is formed on the fifth interlayer insulating film 120. A surface protective film 122 is formed so as to cover the fifth interlayer insulating film 120 and the wiring line 121. The fifth interlayer insulating film 120 is made of, for example, silicon oxide and the wiring line 121 is made of, for example, aluminum (Al) or copper (Cu).

A predetermined potential is applied to the upper electrode 115 of the capacitor Cap. Therefore, this structure can function as a DRAM that stores information by determining whether charge is stored in the capacitor Cap.

When the metal oxide film formed by the method according to the invention is used as the capacitor insulating film 114 of the capacitor Cap, it is possible to maintain leakage current characteristics. Therefore, it is possible to provide the capacitor Cap with high reliability. When a DRAM including the capacitor Cap is formed, it is possible to provide a high-performance device with high data storage characteristics even though the degree of integration (miniaturization) of the device increases.

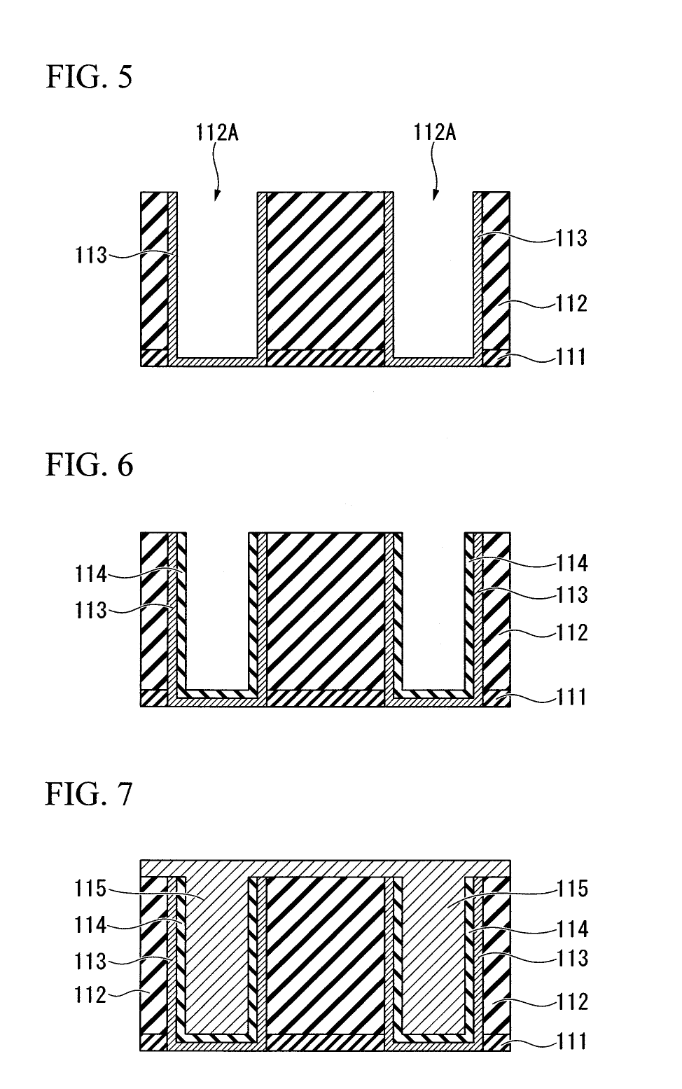

A method of manufacturing the capacitor Cap of the semiconductor device will be described with reference to FIGS. 5 to 7.

FIGS. 5 to 7 are cross-sectional views illustrating the cross section of only a portion on the third interlayer insulating film 111. Hereinafter, processes will be described sequentially.

As shown in FIG. 5, the fourth interlayer insulating film 112 is formed so as to cover the third interlayer insulating film 111. Then, holes 112A are formed in the fourth interlayer insulating film 112 by a photolithography technique such that the surface of the third interlayer insulating film 111 is exposed. The capacitor Cap will be formed in the holes 112A.

A material for the bottom electrode 113 is deposited on the fourth interlayer insulating film 112 and in the holes 112A. The bottom electrode 113 is formed by a dry etching technique or a CMP (Chemical Mechanical Polishing) technique so as to cover the inner wall and the bottom of the hole 112A. The bottom electrode 113 may be made of a refractory metal material. In particular, it is preferable that the bottom electrode 113 be made of a metal film made of a material with high oxidation resistance, such as ruthenium (Ru), iridium (Ir), or platinum (Pt).

As shown in FIG. 6, a metal nitride film, for example a titanium nitride film not shown, with a thickness of for example 1 nm is deposited by the ALD method so as to cover the inner wall and the bottom of the bottom electrode 113. A cycle of oxidizing the metal nitride film and converting into a metal oxide film, for example a titanium oxide film, is repeated about 8 times to about 10 times to form the capacitor insulating film 114 with a thickness of about 10 nm, which is a stacked film structure of metal oxide films, the metal oxide film on the fourth interlayer insulating film 112 is not shown. In this case, the method of depositing the metal nitride film is not limited to the ALD method, but may be the CVD method described in the second embodiment. The kind of metal material is not particularly limited. The thickness of a film formed in one cycle and the number of cycles are not limited to the above-mentioned values.

As shown in FIG. 7, the same metal film as the bottom electrode 113 is deposited so as to fill up the hole 112A and cover the upper surface of the fourth interlayer insulating film 112, thereby forming the upper 115 electrode. In this case, the kind of metal film forming the upper electrode 115 may be different from that of the bottom electrode 113. Each of the bottom electrode 113 and the upper electrode 115 may be a stacked film structure including plural kinds of metal materials.

In this way, the capacitor Cap including the capacitor insulating film 114, which is a stacked film structure including the metal oxide films, is completed.

A metal oxide film made of a metal material other than the titanium oxide, which is formed by the method according to the embodiment, may be used as the insulating film for forming the capacitor Cap. Specifically, for example, a hafnium oxide film, a zirconium oxide film, an aluminum oxide film, a tantalum oxide film, or a lanthanum oxide film may be used as the metal oxide film.

In addition, a stack of different kinds of metal oxide films, such as a stack of titanium oxide films and aluminum oxide films that are alternatively arranged, may be used as the capacitor insulating film. When different kinds of metal oxide films are stacked, a cycle of forming each metal nitride film including a metal material with a thickness of 3 nm or less and oxidizing the metal nitride film may be repeated while changing the kind of metal material included in the source gas.

This embodiment is not limited to the capacitor Cap, but may be applied to the gate insulating film of the MOS transistor Tr1 using the metal oxide film. In this case, the laminating process and the oxidizing process according to this embodiment are repeatedly performed on the semiconductor substrate of the MOS transistor Tr1 (not shown) to form the gate insulating film, which is the capacitor insulating film 114. A gate electrode is formed on the gate insulating film using a conductive film.

When the embodiment is applied, it is possible to form the capacitor Cap with a high capacitance value while preventing the occurrence of a blister between the capacitor insulating film 114 and the bottom electrode 113. When the embodiment is used for a gate insulating film of a transistor, it is possible to form a high-K gate insulating film with a small leakage current and high capacitance.

### Example 1

As Example 1, a process of finally forming a titanium oxide film using the ALD method will be described below. Before Example 1, a semiconductor substrate with the bottom electrode 113 for the capacitor Cap is formed. The semiconductor substrate is placed into a reaction chamber of an ALD deposition apparatus.

It is known that, when the titanium nitride film is oxidized to form a titanium oxide film, two kinds of titanium oxide films having a rutile phase and an anatase phase are formed due to a difference in the nitridation structure of the titanium nitride film. While the anatase phase has a relative permittivity of about 40, the rutile phase has a high relative permittivity of about 80. It is preferable that a titanium oxide film having the rutile phase with high relative permittivity be used as the dielectric film of the capacitor Cap.

In the following example, a titanium oxide film mainly having the rutile phase was formed by the method according to the invention.

In Step S1, TiCl₄ was supplied into the reaction chamber having the semiconductor substrate provided therein for 5 seconds, and then the supply of TiCl₄ stopped. Then, evacuation was performed for 2 seconds without supplying any gas into the reaction chamber. At that time, the formation temperature was set to 400° C.

In Step S2, a N₂ gas for purge was supplied into the reaction chamber for 10 seconds and then the supply of the N₂ gas stopped. Then, evacuation was performed for 2 seconds without supplying any gas into the reaction chamber.

In Step S3, a NH₃ gas was supplied into the reaction chamber for 5 seconds and then the supply of the NH₃ gas stopped. Then, evacuation was performed for 2 seconds without supplying any gas into the reaction chamber.

In Step S4, the N₂ gas for purge was supplied into the reaction chamber for 10 seconds again and then the supply of the N₂ gas stopped. Then, evacuation was performed for 2 seconds without supplying any gas into the reaction chamber. In this case, NH₃ reacted with TiCl₄ adsorbed to the surface of the bottom electrode 113 by Steps S1 to S4 and a titanium nitride film with a thickness corresponding to one cycle of the ALD method was formed on the surface of the bottom electrode 113. Steps S1 to S4 were repeatedly performed to form a stacked film structure including the titanium nitride films with a thickness of 3 nm or less.

In Step S5, an O₂ gas was supplied into the reaction chamber for 5 seconds and then the supply of the O₂ gas stopped. Then, evacuation was performed for 2 seconds without supplying any gas into the reaction chamber.

In Step S6, the N₂ gas for purge was supplied into the reaction chamber for 10 seconds again and then the supply of the N₂ gas stopped. Then, evacuation was performed for 2 seconds without supplying any gas into the reaction chamber.

The titanium oxide film formed in this example was crystallized and the evaluation of the titanium oxide film by X-ray diffraction (XRD) showed that the rutile phase and the anatase phase were mixed at a ratio of about 8:2. In Example 1, the NH₃ gas was not particularly activated and used. However, when NH₃ is insufficiently decomposed, NH₃ may be activated by the remote plasma method and then introduced into the reaction chamber.

### Example 2

As Example 2, a process of finally forming a titanium oxide film using the CVD method will be described below. Before Example 1, a semiconductor substrate with the bottom electrode 113 for the capacitor Cap is formed. The semiconductor substrate is put into a reaction chamber of a CVD deposition apparatus.

In Step S1, a source gas including TiCl₄ and NH₃ was supplied into the reaction chamber of the CVD deposition apparatus having the semiconductor substrate provided therein to form a titanium nitride film with a thickness of 1 nm on the surface of the bottom electrode 113. After the titanium nitride film was formed, the supply of the source gas stopped and evacuation was performed for 2 seconds without supplying any gas into the reaction chamber. At that time, the formation temperature was set to 580° C. In addition, with regard to the source gas, 10% of He-diluted TiCl₄ gas flowed at 100 sccm, the NH₃ gas flowed at 100 sccm, and pressure was set to 0.2 Torr.

In Step S2, a N₂ gas for purge was supplied into the reaction chamber and then the supply of the N₂ gas stopped. Then, evacuation was performed for 2 seconds without supplying any gas into the reaction chamber. In Step S3, a NH₃ gas was supplied into the reaction chamber for 20 seconds and then the supply of the NH₃ gas stopped. Then, evacuation was performed for 2 seconds without supplying any gas into the reaction chamber. At that time, the flow rate of the NH₃ gas was 100 sccm.

In Step S4, the N₂ gas for purge was supplied into the reaction chamber again and then the supply of the N₂ gas stopped. Then, evacuation was performed for 2 seconds without supplying any gas into the reaction chamber.

In Step S5, an O₂ gas was supplied into the reaction chamber at 100 sccm for 60 seconds and then the supply of the O₂ gas stopped. Then, evacuation was performed for 2 seconds without supplying any gas into the reaction chamber.

In Step S6, the N₂ gas for purge was supplied into the reaction chamber again and then the supply of the N₂ gas stopped. Then, evacuation was performed for 2 seconds without supplying any gas into the reaction chamber.

The titanium oxide film formed in this example was crystallized and the evaluation of the finally obtained titanium oxide film by X-ray diffraction (XRD) showed that the rutile phase and the anatase phase were mixed at a ratio of about 9:1.

### Comparative Example

A method of manufacturing a semiconductor device according to the related art will be described as a comparative example of the method of manufacturing the semiconductor device according to the invention. A case in which a titanium oxide film is formed as an example of forming the metal oxide film will be described. An application to a DRAM with a design rule of 50 nm or less was assumed and a titanium oxide film with a thickness of about 10 nm was formed as an insulating film for a capacitor.

A silicon oxide film was formed so as to cover a silicon substrate, and a platinum (Pt) film was formed thereon by a PVD (sputtering) method, which was the bottom electrode 113. Then, a titanium nitride film with a thickness of about 7 nm was formed as the capacitor insulating film 114 on the bottom electrode 113 by a CVD method using TiCl₄ and NH₃ as a source gas. Then, the formed titanium nitride film was oxidized for 10 minutes under the conditions of a formation temperature of 550° C., atmospheric pressure, and an oxygen atmosphere to form a titanium oxide film with a thickness of about 10 nm.

The observation result of the titanium oxide film shows that a blister occurred between the titanium oxide film and the bottom electrode 113. When a capacitor was formed using the capacitor insulating film in this state, a leakage current increased and it was difficult to obtain desired characteristics.

As another method, a titanium nitride film with a thickness of more than 3 nm was oxidized under the conditions where oxidation power was reduced such that no blister occurred. As a result, nitrogen remained in the titanium oxide film and a titanium oxynitride (TiON) was formed. Therefore, in the capacitor using the titanium oxide film as the capacitor insulating film 114, it was difficult to obtain desired characteristics due to the titanium oxynitride in the titanium oxide film.

The embodiment can be applied to semiconductor devices including DRAMs, capacitors, or MOS transistors.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a metal nitride film with a thickness of 3 nm or less over a substrate;
oxidizing the metal nitride film to form a metal oxide film; and
repeating a set of the formation of the metal nitride film and the oxidation of the metal nitride film, to form a stack of the metal oxide films over the substrate.

2. The method according to claim 1, wherein the metal nitride film is formed by an atomic layer deposition process.

3. The method according to claim 2, wherein the atomic layer deposition process comprising:
forming a metal film including a metal material of the metal nitride film;
carrying out a nitridation of the metal film by supplying a nitriding gas onto the metal film; and
repeating the formation of the metal film and the nitridation of the metal film, to form a stack of the metal nitride films over the substrate.

4. The method according to claim 3, further comprising:
forming an electrode over the substrate before forming the metal film, wherein forming the metal film is performed by absorbing the metal material on a surface of the electrode.

5. The method according to claim 1, wherein the metal nitride film comprises a nitride of at least one metal which is selected from the groups consisting of titanium, aluminum, hafnium, zirconium, tantalum, and lanthanum.

6. The method according to claim 1, wherein forming the metal film is performed by supplying a source gas to the substrate, the source gas comprises at least one of TiCl₄, Ti(OCHMe₂)₄, tetramethoxy titanium, and Ti[N(CH₃)₂]₄.

7. The method according to claim 1, wherein the nitriding gas is an NH3 gas.

8. The method according to claim 1, wherein the NH₃ gas is activated by a remote plasma process.

9. The method according to claim 1, wherein the metal nitride film is oxidized in an atmosphere which contains at least one of oxygen, ozone, a mixture gas of oxygen and ozone, and nitrogen monoxide.

10. The method according to claim 1, wherein the metal nitride film is formed by a chemical vapor deposition process.

11. The method according to claim 10, wherein a source gas including TiCl₄ and NH₃ is supplied to the substrate to form the metal nitride film.

12. The method according to claim 1, wherein the metal nitride film is formed with a thickness of 1 nm or less.

13. The method according to claim 1, wherein the metal nitride film is formed with a thickness of 0.5 nm or less.

14. The method according to claim 1, wherein the metal oxide film is a titanium oxide film having mainly a rutile crystal phase.

15. The method according to claim 1, wherein the metal nitride film is formed in a temperature range from 400° C. to 600° C.

16. A method of forming a semiconductor device, the method comprising:
forming a metal nitride film with a predetermined thickness over a substrate;
oxidizing the metal nitride film to form a metal oxide film; and
repeating a set of the formation of the metal nitride film and the oxidation of the metal nitride film, to form a stack of the metal oxide films over the substrate,
wherein the predetermined thickness is set to prevent an occurrence of a blister under the metal oxide film due to the oxidizing of the metal nitride film.

17. The method according to claim 16, wherein the metal oxide film is a titanium oxide film.

18. The method according to claim 17, wherein the titanium oxide film includes a rutile crystal phase mainly.

19. The method according to claim 18, wherein the predetermined thickness is set to 3 nm or less.

20. The method according to claim 18, wherein the predetermined thickness is set to 0.5 nm or less.
